(19) United States
(12) Patent Application Publication
(10) Pub. No.: US 2009/0159007 A1
(43) Pub. Date: Jun. 25, 2009

(54) SUBSTRATE SUPPORT

(75) Inventor: Ikuma MOROOKA, Handa-shi (JP)

Correspondence Address: BURR & BROWN, PO BOX 7068, SYRACUSE, NY, 13261-7068, US

(73) Assignee: NGK Insulators, Ltd., Nagoya-Shi (JP)

(21) Appl. No.: 12/270,005

(22) Filed: Nov. 13, 2008

(30) Foreign Application Priority Data
Nov. 14, 2007 (JP) 2007-295642
Nov. 12, 2008 (JP) 2008-290086

(51) Int. Cl. C23C 16/513

(52) U.S. Cl. 118/728; 204/298.31

(57) ABSTRACT

A substrate support according to the present invention includes a ceramic base 12 having an upper surface on which a substrate is placed; a first conductive body 16 having a plate-type body, composed of a conductive paste that is sintered, and embedded in an upper side of the ceramic base 12; a second conductive body 18 having a meshed-type body, provided inside the ceramic base 12, and being in contact with a lower surface of the first conductive body 16; and an electrode terminal 20 penetrating a part of the ceramic base 12 from a lower surface of the ceramic base 12 and is connected to the second conductive body 18.

### CROSS REFERENCE TO RELATED APPLICATION

This application is based upon and claims the benefit of priority from prior a Japanese Patent Application No. 2007-295642, filed on Nov. 14, 2007; and a Japanese Patent Application No. 2008-290086, filed on Nov. 12, 2008, the entire contents of which are incorporated herein by reference.

### BACKGROUND OF THE INVENTION

1. Field of the Invention

The present invention relates to a substrate support used in a plasma processing apparatus.

2. Description of the Related Art

In a process of manufacturing an electronic device such as a semiconductor device and a liquid crystal device, processing by use of plasma (plasma processing) such as a dry etching, a chemical vapor deposition (CVD) and a surface modification is carried out. For example, in a reactive ion etching (RIE) or the like, a substrate is placed on a substrate support having a ceramic base and being provided in a processing chamber of a plasma etching apparatus. Then, the substrate is electrostatically chucked onto the substrate support, by the electrode (embedded electrode) embedded in the substrate support. Here, a high-frequency current is applied from a high-frequency power source through the embedded electrode, and a gas introduced to the processing chamber in which the air is evacuated to be a vacuum state. Thus, plasma is generated, and an etching process on the substrate is performed by the ion included in the plasma thus generated.

Aluminum nitride (AlN), alumina (Al₂O₃), yttria (Y₂O₃) or the like is used for the substrate support, from the viewpoint of a plasma resistance, an electrical insulation, a contamination-free, a thermal conductivity and the like. A meshed-type conductive body, a screen-printed conductive paste or the like may be used as the embedded electrode (see Japanese Patent No. 2813154 and Japanese Patent Application Publication No. 2006-282502, for examples).

An embedded electrode using the meshed-type conductive body can have a low resistance by appropriately selecting a wire diameter and a mesh coarseness of the meshed-type conductive body. Accordingly, a large high-frequency current can be applied to the embedded electrode using the meshed-type conductive body, whereby high-density plasma can be generated constantly. However, the thickness distribution of the dielectric film composed of the ceramic base placed on the embedded electrode is not in uniform, since the thickness of the dielectric film is affected by the form of the embedded electrode. Therefore, uneven absorbability for electrostatic chuck force of the substrate occurs. In addition, the plasma distribution also becomes ununiform, thereby the electrostatic breakdown of the ceramic base is more likely to occur.

Meanwhile, in the embedded electrode formed by using a screen printing, the thickness distribution of the dielectric film composed of the ceramic base placed on the embedded electrode is in uniform. However, it is difficult to form a thick embedded electrode, and an embedded electrode formed by the screen printing inevitably has a high resistance value. Therefore, it is difficult to apply a large high-frequency current to the embedded electrode. Moreover, localized heat is generated because of the uneven film thickness of the embedded electrode, thereby causing the wire disconnection and the like that degrades a durability of the embedded electrode.

In particular, in the process of manufacturing the embedded electrode by using the screen printing, the conductive component and the ceramic component sometimes react with each other at a high temperature, and the resistance of the embedded electrode becomes high. In this case, it is difficult to apply a large high-frequency current to the embedded electrode.

### SUMMARY OF THE INVENTION

An object of the present invention is to provide a substrate support that can reduce a resistance on the embedded electrode, and can generate the plasma uniformly.

An substrate support according to an aspect of the present invention includes: (a) a ceramic base composed of any one of aluminum nitride (AlN), alumina (Al₂O₃), yttria (Y₂O₃), silicon nitride (Si₃N₄), silicon carbide (SiC) and boron nitride (BN), and having an upper surface on which a substrate is placed; (b) a first conductive body having a plate-type body, composed of a conductive paste that is sintered, and embedded in an upper side of the ceramic base; (c) a second conductive body having a meshed-type body, provided inside the ceramic base, and being in contact with a lower surface of the first conductive body; and (d) an electrode terminal penetrating a part of the ceramic base from a lower surface of the ceramic base and being connected to the second conductive body. The conductive paste composing the first conductive body includes at least a high melting point metal composed of any one of molybdenum (Mo), niobium(Nb) and tungsten(W), or a high melting point metal carbide composed of any one of Mo, Nb, and W.

### BRIEF DESCRIPTION OF THE DRAWINGS

FIG. 1 is a diagram showing an example of a substrate support according to an embodiment of the present invention.

FIG. 2 is a schematic view showing a cross section A-A of the substrate support shown in FIG. 1.

FIG. 3 is a diagram showing an example of a plasma processing apparatus used for describing the embodiment of the present invention.

FIG. 4 is a first cross-sectional view showing an exemplar manufacturing method of the substrate support according to the embodiment of the present invention.

FIG. 5 is a second cross-sectional view showing the exemplar manufacturing method of the substrate support according to the embodiment of the present invention.

FIG. 6 is a third cross-sectional view showing the exemplar manufacturing method of the substrate support according to the embodiment of the present invention.

FIG. 7 is a fourth cross-sectional view showing the exemplar manufacturing method of the substrate support according to the embodiment of the present invention.

FIG. 8 is a diagram showing an exemplar plasma processing apparatus used to evaluate the substrate support according to the embodiment of the present invention.

FIG. 9 is a table showing an exemplar evaluation result of the substrate support according to the embodiment of the present invention.

FIG. 10 is a table showing an exemplar evaluation result of the substrate support according to the embodiment of the present invention.

### DETAILED DESCRIPTION OF PREFERRED EMBODIMENTS

Hereinafter, an embodiment of the present invention will be described with reference to the accompanying drawings. The same or similar symbols are assigned to the same or similar portions in the following description of the drawings. However, it should be noted that the drawings are schematic, and relations between thicknesses and planar dimensions, ratios between layer thicknesses and the like differ from those in actuality. Accordingly, specific thicknesses and dimensions should be determined in consideration of the following description. Moreover, relations between dimensions and between ratios also differ among some of the drawings, as a matter of course.

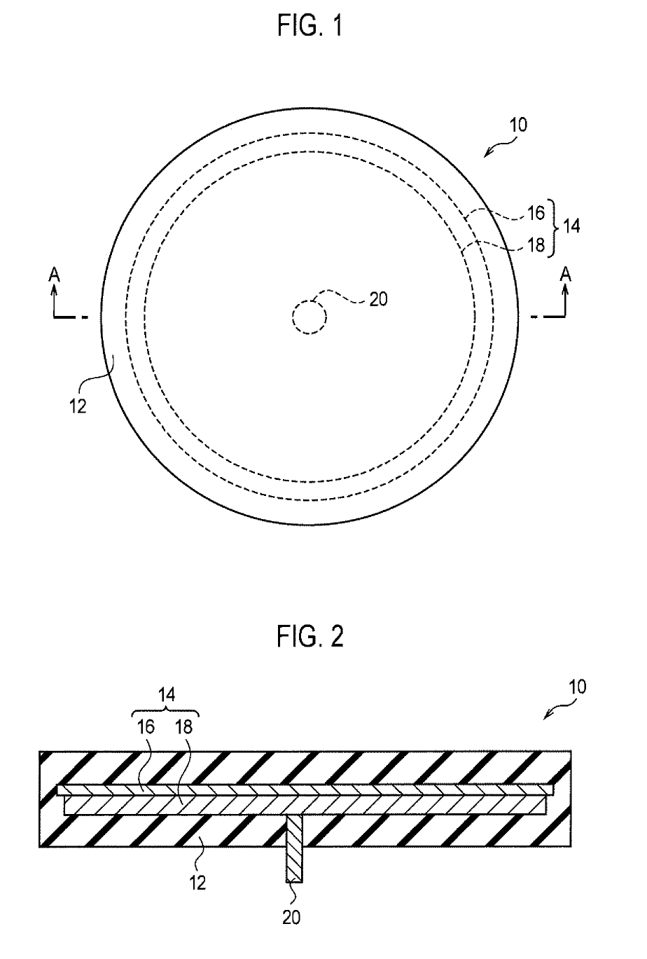

As shown in FIGS. 1 and 2, a substrate support 10 according to an embodiment of the present invention includes a ceramic base 12, an embedded electrode 14, an electrode terminal 20 and the like. The embedded electrode 14 includes a first conductive body 16 having a plate-type body and a second conductive body 18 having a meshed-type body. The first conductive body 16 is embedded in an upper side of the ceramic base 12. The second conductive body 18 is provided inside the ceramic base 12 and is in contact with a lower surface of the first conductive body 16. The electrode terminal 20 penetrates a part of the ceramic base 12 from a lower surface of the ceramic base 12 and is connected to the second conductive body 18.

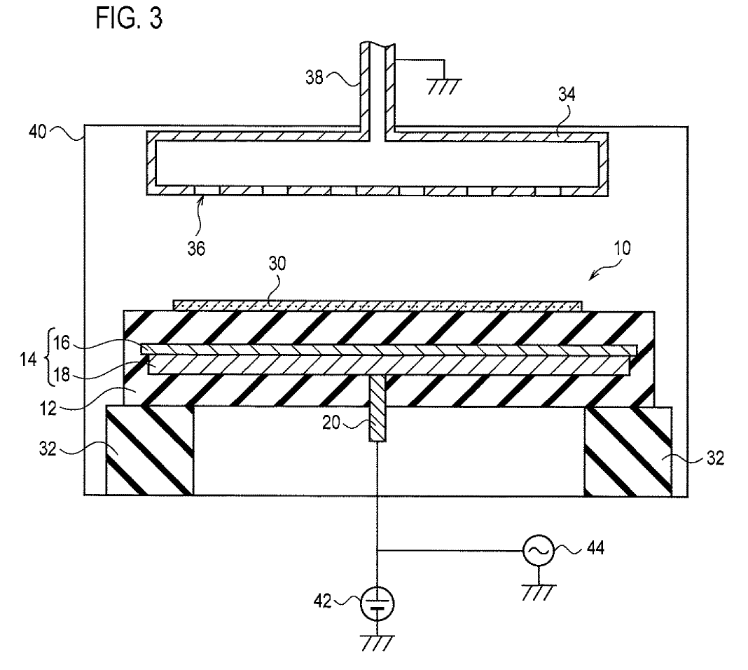

As shown in FIG. 3, the substrate support 10 shown in FIGS. 1 and 2 is attached to a holding member 32 in a processing chamber 40 of a plasma etching apparatus, for example. For example, when a substrate 30 being an object to be processed is a circular semiconductor substrate, the substrate support 10 is formed in a disk shape. The substrate 30 is placed on an upper surface of the substrate support 10, and is electrostatically chucked by the embedded electrode 14. The embedded electrode 14 is connected to a direct current power source 42 provided outside the processing chamber 40, through the electrode terminal 20. A counter electrode 34 is provided so as to face the substrate 30. An etching gas or the like is introduced through a gas piping 38 to the inside of the counter electrode 34. A plurality of gas inlets 36 is provided on a surface of the counter electrode 34 that faces the substrate 30. The etching gas is introduced to the processing chamber 40 through one of the gas inlets 36, and plasma is excited between a surface of the substrate 30 and the grounded counter electrode 34 by a high-frequency power source 44 connected to the embedded electrode 14.

A ceramic material such as aluminum nitride (AlN), alumina (Al₂O₃), yttria (Y₂O₃), silicon nitride (Si₃N₄), silicon carbide (SiC) and boron nitride (BN) is used as the ceramic base 12.

As the first conductive body 16, a sintered conductive paste containing a conductive material is used. Examples of the conductive material include a high melting point metal such as tungsten (W), molybdenum (Mo) and niobium (Nb), or high melting point metal carbide such as tungsten carbide (WC). It is more preferable that the first conductive body 16 includes the ceramic material of approximately 5 wt % to 30 wt %, so that a thermal expansion coefficient of the electrode may become closer to that of the ceramic.

As the second conductive body 18, a conductive material having a meshed-type body of a high melting point metal such as Mo, Nb and W, or high melting point carbide such as WC is used.

In the substrate support 10 according to the embodiment of the present invention, the first conductive body 16 is provided on the side of the surface of the ceramic base 12, the surface on which the substrate 30 is placed. The first conductive body 16 is a sintered conductive paste, which is formed flatly by the screen printing and the like. Accordingly, a dielectric film thickness distribution of the ceramic base 12 on the embedded electrode 14 can be made uniform, whereby unevenness in the adsorbability for the substrate 30 can be suppressed.

Moreover, the second conductive body 18 is placed so as to come into contact with the first conductive body 16. In the second conductive body 18, resistance can be lowered by appropriately selecting the mesh wire diameter and the mesh coarseness of the meshed-type conductive material. For this reason, a large high-frequency current can be applied to the embedded electrode 14, whereby high-density plasma can be generated constantly. Additionally, plasma can be generated uniformly since the dielectric film thickness on the embedded electrode 14 is uniform.

In order to form a substrate support having a high shear strength and durability, it is preferable that the conductive materials composing the first conductive body 16 and the second conductive body 18 have similar thermal expansion rates. Specifically, it is preferable that a conductive material contained in the conductive paste forming the first conductive body 16 is used for the second conductive body 18.

In the same manner, it is preferable that a material forming the ceramic base has a similar thermal expansion rate to a conductive material composing the first conductive body 16 and the second conductive body 18. In particular, it is preferable that the difference in thermal expansion rate between the ceramic base and the conductive material composing the first conductive body 16 and the second conductive body 18 respectively is kept as small as possible.

For instance, when Al₂O₃ is used as the material of the ceramic base, WC having a thermal expansion coefficient of approximately 6.2×10⁻⁶/K, or Nb having a thermal expansion coefficient of approximately 7.1×10⁻⁶/K is preferably used, since the thermal expansion coefficient of Al₂O₃ is approximately 8×10⁻⁶/K. Meanwhile, when AlN (linear expansion coefficient of approximately 5×10⁻⁶/K) is used as the material of the ceramic base, W (approximately 4.5×10⁻⁶/K) or Mo (approximately 5.2×10⁻⁶/K) is preferably used. When Si₃N₄ (approximately 3.2×10⁻⁶/K) is used as a material of the ceramic base, W or Mo is preferably used, and When Y₂O₃ (approximately 8×10⁻⁶/K) is used as a material of the ceramic base, WC or Nb is preferably used.

Moreover, as for the first conductive body 16, a printed conductive body formed of a paste in which 5 wt % to 30 wt % of powder (preferably having a particle size of 1-3 μm) of the same material composing the ceramic base is mixed may be used instead of the plain metal. This is preferable since the thermal expansion coefficient of the mixture can be approximated to the thermal expansion coefficient of the ceramic base. The mixture has no effect when the powder is mixed less than 5 wt %, Meanwhile, the conductive property of the first conductive body 16 is markedly lowered if the powder is mixed for more than 30 wt %, since connection of the conductive materials is largely suppressed by the insulating ceramic. Thus, the ceramic powder in the first conductive body 16 and the ceramic of the surrounding ceramic base are strongly bonded by the sintering, and a peeling durability of the first conductive body 16 can be made higher than the case of using the plain metal. Accordingly, reliability of the ceramic members can be improved, In this case, some differences between the thermal expansion coefficients of the conductive material and the ceramic base are acceptable. Meanwhile, a reaction sometimes occurs between metal and ceramic (particularly oxide) from raised temperature in the process of manufacturing, and a conductivity of the conductive body becomes lower than that of the plain metal. For this reason, it is most preferable that a mixture of ceramic powder and WC, which is less likely to react with ceramic, is used as the first conductive body 16. However, it is essential to use the second conductive body 18 of the present invention since the deterioration in conductivity is inevitable caused by the mixture of ceramic powder. As the second conductive body 18, W, Mo or Nb is preferably used because it can be easily processed into a meshed-type body, and Mo or Nb is most preferably used from the viewpoint of ductility.

As for the first conductive body 16, the desired diameter is approximately 285 mm to 295 mm, while the desired thickness is approximately 10 μm to 30 μm. The conductivity of the first conductive body 16 may possibly be lowered markedly from the reaction with the surrounding ceramic if the thickness is 10 μm or less. If the thickness is 30 μm or more, the peeling durability may possibly be lowered markedly due to the difference between thermal expansion coefficients or the fact that the conductive body itself is not sufficiently strong. As for the second conductive body 18, the desired wire diameter is approximately 0.05 mm to 0.35 mm, while the desired mesh coarseness is approximately #24 to #100. A second conductive body 18 having a meshed-type body, being practically easy to form, and being sufficiently strong can be obtained by employing the above wire diameter and mesh coarseness.

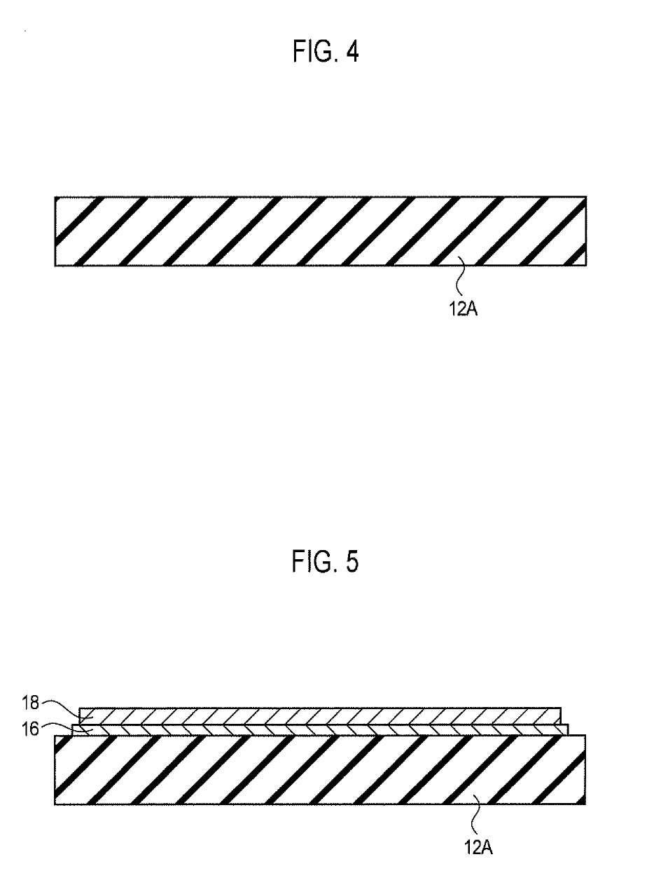

Next, a manufacturing method of the substrate support 10 shown in FIGS. 1 and 2 will be described with reference to FIGS. 4 to 7.

(a) As a ceramic precursor powder, an Al₂O₃ powder (particle size of approximately 1 μm) having approximately 99.5% purity and a magnesium oxide (MgO) powder being a sintering additive are used, for example. Approximately 0.04 wt % MgO powder is contained in the ceramic precursor powder. A polyvinyl alcohol (PVA) being a binder, water and a dispersing agent is added to the ceramic precursor powder and mixed in a trommel for approximately 16 hours to produce a slurry. The slurry thus obtained is subjected to spray drying by a spray dryer. Then, approximately 5 hours of calcinations process is performed at about 500° C. for removing the binder. Thus, a ceramic powder of granules having a mean particle size of approximately 80 μm is produced. Note that the ceramic powder may be produced without performing the calcinations process after the slurry is subjected to the spray drying.

(b) As shown in FIG. 4, a mold is filled with the ceramic powder and press forming is carried out with a pressure of approximately 200 kg/cm². This molded body is attached to a carbon sheath and sintered by a hot-press sintering method to produce a sintered body 12A. The sintering is carried out in a pressurized nitrogen atmosphere (150 kPa), by a heat-up rate of approximately 300° C. per hour under a pressure of about 100 kg/cm², and is stored for about 2 hours at approximately 1600° C. The sintered body 12A is ground to produce a disk having a diameter of approximately 340 mm and a thickness of approximately 6 mm. Through the grinding process, one surface of the sintered body 12A is smoothed so that the surface roughness Ra of approximately 0.8 pm or less can be obtained.

(c) As shown in FIG. 5, a conductive paste is applied to the smoothed surface of the sintered body 12A by the screen printing, so as to form a first conductive body 16 having a diameter of approximately 290 mm and a thickness of approximately 15 μm. A second conductive body 18 formed of a conductive material having a meshed-type body is placed on top surface of the first conductive body 16 before the first conductive body 16 dries. Thereafter, a jig is placed on the top surface of the second conductive body 18 to apply a load to the whole conductive bodies so that the first conductive body 16 and the second conductive body 18 can be bonded together. The conductive paste is produced by mixing, for example, a WC powder, an alumina powder (content of approximately 5 to 30 wt %) and terpineol being a binder. The conductive material having a meshed-type body is WC, for instance, and has a diameter of approximately 288 mm, a mesh wire diameter of approximately 0.12 mm and a mesh coarseness of #50. Incidentally, the mesh coarseness refers to the number of mesh wires per inch.

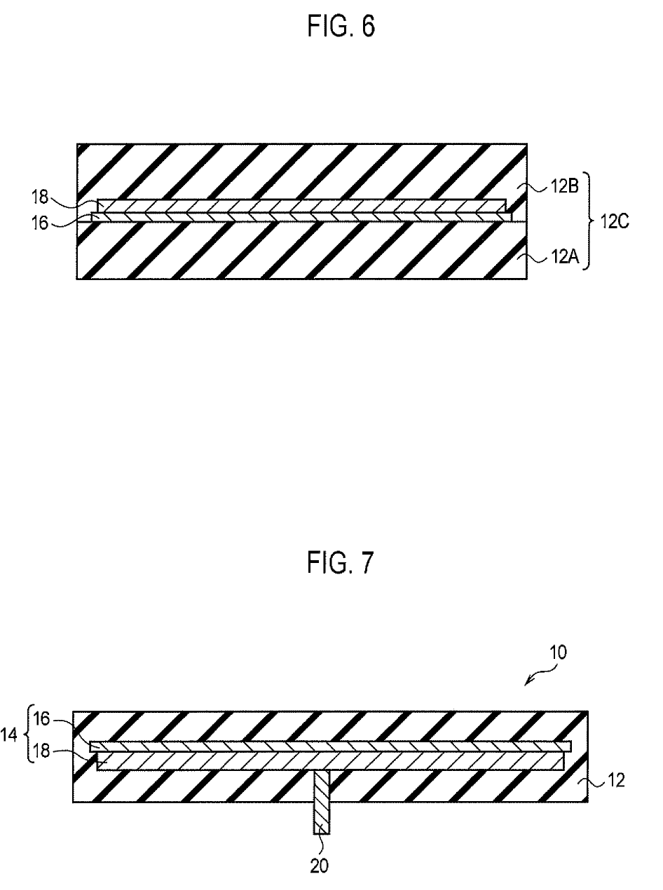

(d) Next, the sintered body 12A on which the first and second conductive bodies 16 and 18 are formed is attached to the mold. As shown in FIG. 6, the mold is filled with the ceramic powder, and a press forming is carried out with a pressure of approximately 200 kg/cm2. Thereafter a molded body 12B is formed on top of the sintered body 12A and first and second conductive bodies 16 and 18, thus producing a ceramic base 12C. Subsequently, the ceramic base 12C thus produced is attached to a carbon sheath and is sintered by a hot-press sintering method. Thus, the ceramic base 12C in which the first and second conductive bodies 16 and 18 are embedded is produced, Subsequently, the ceramic base 12C thus produced is attached to a carbon sheath, and sintered by a hot-press sintering method to produce a ceramic base 12 in which a first and second conductive bodies 16 and 18 are embedded. Here, the ceramic base 12 C is sintered in a pressurized nitrogen atmosphere (150 kPa), by a heat-up rate of approximately 300° C. per hour under a pressure of about 100 kg/cm², and is stored for about 2 hours at approximately 1600° C.

(e) As shown in FIG. 7, a surface of the ceramic base 12 is subjected to a surface grinding by a diamond grindstone to adjust the thickness of the ceramic base 12 to be approximately 14 mm. Note that the ceramic sintered body once sintered in the process of (b) is sintered again in the process of (d). At this time, the sintered body obtained in the process of (b) is processed so as to form a surface on which a substrate that adsorbs a wafer and the like in an electrostatic chuck is placed. Additionally, a side surface of the ceramic base 12 is ground. Moreover, a hole that reaches the first conductive body 16 from the back side of the ceramic base 12 is formed, and an electrode terminal 20 is bonded to the first conductive body 16 by use of an aluminum powder. Thus, the substrate support 10 shown in FIGS. 1 and 2 is manufactured.

Various properties of the substrate support 10 thus manufactured are evaluated. For example, a counter electrode having a diameter of approximately 20 mm is caused to be in contact with any point on the surface of the ceramic base 12, and a capacitor is formed by the counter electrode and the embedded electrode 14, while the dielectric film is interposed therebetween, Here, by measuring the capacitance, a dielectric film thickness of the ceramic base 12 on the embedded electrode 14 is evaluated. A flatness of the substrate adsorbing surface of the electrostatic chuck is approximately 20 μm or less. Here, a flatness of the embedded electrode 14 is calculated from a coordinate obtained by subtracting the dielectric film thickness from a measurement point coordinate of the substrate adsorbing surface. A resistance value of the embedded electrode 14 is measured by an impedance analyzer. A shear strength between the embedded electrode 14 and the ceramic base 12 is measured using a complex interlayer property evaluation apparatus which applies the microdroplet method or the like to a disk-shaped test piece. Here, the disk-shaped test piece is cut out from the manufactured substrate support 10 so as to include the embedded electrode 14 and to have a diameter of approximately 10 mm. An insulation breakdown voltage is measured by a method in conformity with Japan Industrial Standard (JIS) C2141. A terminal strength of the electrode terminal 20 is measured by use of a tensile strength test.

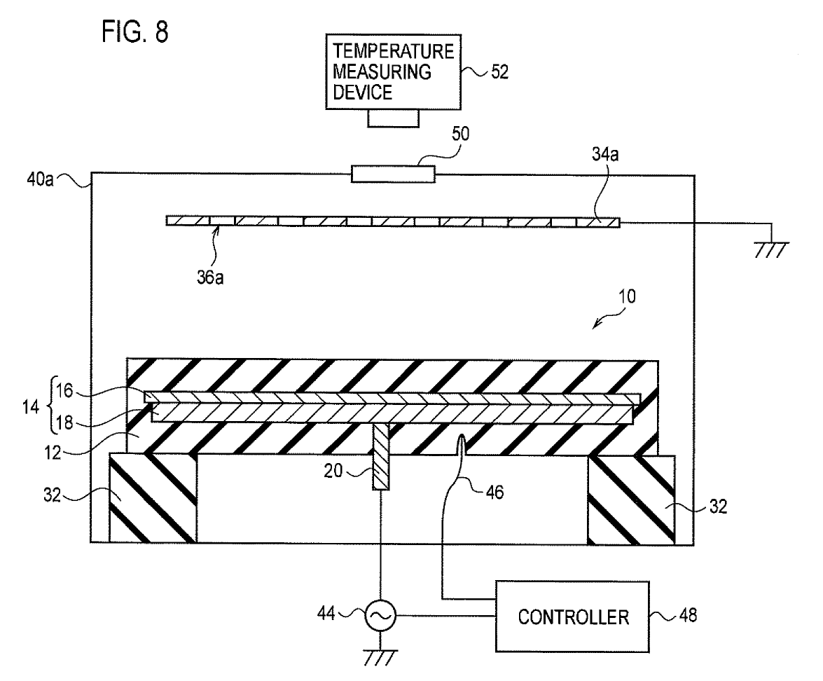

Further, as shown in FIG. 8, a current-carrying capacity, plasma uniformity, durability and the like are measured by attaching the substrate support 10 to a processing chamber 40a of a plasma processing apparatus. A gas such as argon (Ar) is introduced to the processing chamber 40a with a pressure of approximately 3 Pa, and plasma is excited between the surface of the ceramic base 12 and a grounded counter electrode 34a by a high-frequency power source 44 connected to the embedded electrode 14. The high-frequency current flown to the embedded electrode 14 can be controlled by a controller 48, which receives feedback of temperature detected by a thermocouple 46. Here, a temperature measuring part of the thermocouple 46 is inserted to a hole provided in the ceramic base 12. A surface temperature of the ceramic base 12 can be detected by a temperature measuring device 52, such as an infrared camera, which detects temperature through a measurement window 50 provided in the processing chamber 40a and through a plurality of holes 36a provided on the counter electrode 34a.

For example, while setting a temperature controlled by the thermocouple 46 to be approximately 100° C., a high-frequency current measured after the elapse of an hour is obtained as a current-carrying capacity. While setting a temperature controlled by the thermocouple 46 to be approximately 100° C., a difference in a temperature distribution on the surface of the ceramic base 12 is obtained as the plasma uniformity. Here, the temperature difference is measured by the temperature measuring device 52. Moreover, durability is evaluated by repeating a cycle of heating up the temperature of the thermocouple 46 from room temperature to approximately 300° C. by plasma, until the substrate support 10 breaks.

### (Evaluation Result 1)

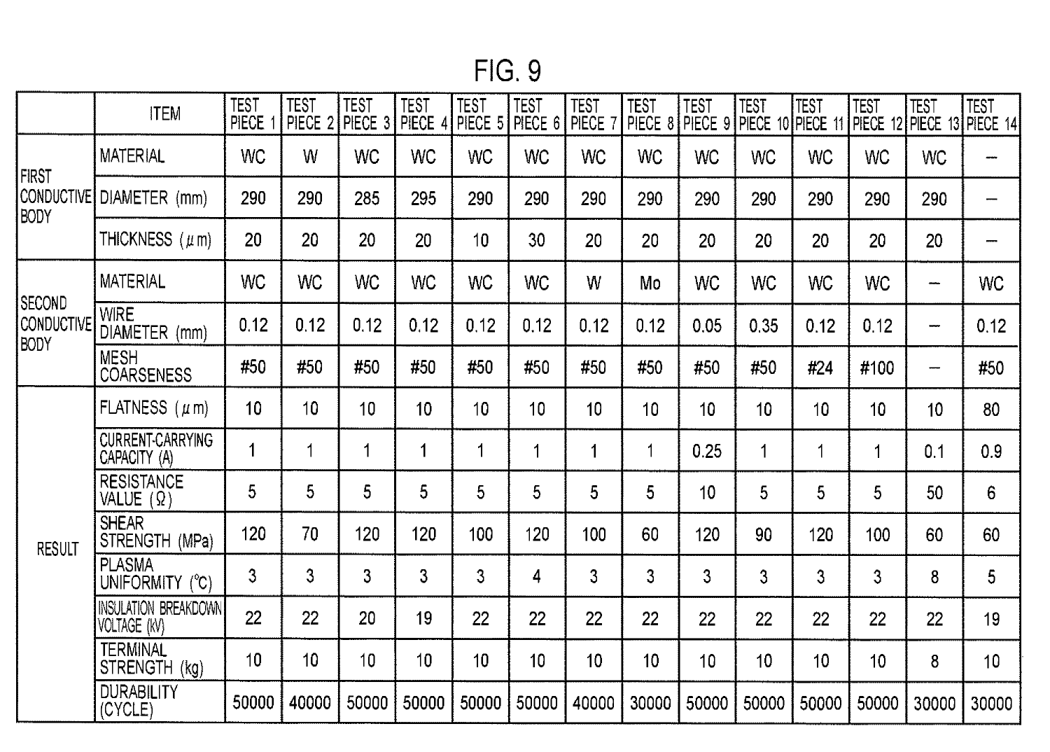

A table in FIG. 9 shows results of evaluation of various properties by taking, as test piece 1, a substrate support manufactured under the conditions described in the manufacturing method according to the embodiment of the present invention. Here, alumina (Al₂O₃) is used as the ceramic base.

Test pieces 2 to 12 are substrate supports manufactured by varying the material, diameter and thickness of the first conductive body 16 as well as the material, the wire diameter, the mesh coarseness and the like of the second conductive body 18. In test piece 2, the material of the first conductive body is changed from tungsten carbide (WC) to W. In test pieces 3 and 4, the diameters of the first conductive bodies are changed to approximately 285 mm and approximately 295 mm, respectively. In test pieces 5 and 6, the thicknesses of the first conductive bodies are changed to approximately 10 μm and approximately 30 μm, respectively. In test pieces 7 and 8, while the thicknesses of the first conductive bodies are approximately 20 μm, the materials of the second conductive bodies are changed to W and Mo, respectively. In test pieces 9 and 10, while the thicknesses of the first conductive bodies are approximately 20 μm, the wire diameters of the second conductive bodies are changed to approximately 0.05 mm and approximately 0.35 mm, respectively. In test pieces 11 and 12, while the thicknesses of the first conductive bodies are approximately 20 μm, the mesh coarseness of the second conductive bodies are changed to approximately #24 and #100, respectively. Additionally, test pieces 13 and 14 are provided as comparative examples, and are substrate supports each provided with the first conductive body alone that is a printed electrode, or the second conductive body alone that is a meshed electrode.

The surface flatness of the embedded electrode of the test piece 1 is approximately 10 μm, and is similar to the test piece 13 in which the embedded electrode is formed of the first conductive body alone.

Meanwhile, as for the test piece 14 in which the embedded electrode is formed of the second conductive body alone, the surface flatness of the embedded electrode is deteriorated to approximately 80 μm.

A current-carrying capacity is mainly determined by a resistance value of the embedded electrode. As for the test pieces 1 and 14 using the second conductive body, the resistance values are reduced to approximately 50 and approximately 60, respectively, and the current-carrying capacities are increased to approximately 1 A and approximately 0.9 A, respectively. Meanwhile, as for the test piece 13 using the first conductive body alone, the resistance value is increased to approximately 50Ω, and the current-carrying capacity is decreased to approximately 0.1 A.

The shear strength is approximately 120 MPa for the test piece 1, while it is lowered to approximately 60 MPa for the test pieces 13 and 14.

The plasma uniformity is approximately 3° C. for the test piece 1, while it is lowered to approximately 8° C. for the test piece 13 and to approximately 5° C. for the test piece 14. As for the test piece 13, not only the resistance of the embedded electrode is high but also the thickness tends to vary, local non-uniformity in plasma is occurred. As for the test piece 14, the dielectric film thickness distribution of the ceramic base provided on the embedded electrode becomes non-uniform, whereby plasma becomes non-uniform.

The insulation breakdown voltage is approximately 22 kV for the test pieces 1 and 13, while it is lowered to approximately 19 kV for the test piece 14. This is because electric field concentration occurs due to the surface flatness of the embedded electrode by affected by the flatness of the surface of the embedded electrode.

The terminal strength is approximately 10 kg for the test pieces 1 and 14 using the second conductive body, while it is deteriorated to approximately 8 kg for the test piece 13 using the first conductive body alone. This is because the first conductive body is peeled off at the portion where the electrode terminal is bonded, in the case where only the printed first conductive body is used.

The durability is approximately 50000 cycles for the test piece 1, while it is lowered to approximately 30000 cycles for the test pieces 13 and 14. This is because the durability is lowered along with the lowering of shear strength.

As has been described, the embodiment of the present invention employs a first conductive body being a sintered conductive paste that can be formed flatly on a dielectric film side of the ceramic base. According to this ceramic base, unevenness in the dielectric film thickness distribution of a ceramic base can be suppressed, and plasma can be generated uniformly. Further, a second conductive body using a low-resistance conductive material having a meshed-type body is provided so as to contact the first conductive body. As a result, a resistance of an embedded electrode can be lowered, whereby high-density plasma can be generated. Moreover, the shear strength between the ceramic base and the embedded electrode can be improved so that a higher durability can be achieved.

In respective the test pieces 2, 7 and 8 in which different materials are used for the first and second conductive bodies, the shear strength is lowered to approximately 70 MPa, approximately 100 MPa and approximately 60 MPa. Along with the lowering of shear strength, the durability is also lowered to approximately 40000 cycles, approximately 40000 cycles and approximately 30000 cycles for the test pieces 2, 7 and 8, respectively, This is because the thermal expansion rates differ between the first and second conductive bodies, and stress is generated therebetween.

As for the test piece 3, the first conductive body has a diameter of approximately 285 mm, which is smaller than the diameter of approximately 288 mm of the second conductive body. Accordingly, end portions of the mesh wires of the second conductive body are exposed at edges of the embedded electrode, and electric field concentration occurs. As a result, the insulation breakdown voltage is lowered to approximately 20 kV. On the other hand, as for the test piece 4, the first conductive body has a large diameter of approximately 295 mm. In this case, the insulation distance with the outer circumference of the ceramic base becomes small, and the insulation breakdown voltage is lowered to approximately 19 kV.

As for the test piece 5 in which the thickness of the first conductive body is made as thin as approximately 10 μm, bonding strength between the first and second conductive bodies becomes insufficient, and the shear strength is lowered to approximately 100 MPa.

On the other hand, as for the test piece 6 in which the thickness of the first conductive body is made as thick as approximately 30 μm, the conductive paste forming the first conductive body droops, and the thickness becomes uneven, For this reason, plasma uniformity is slightly lowered to approximately 4° C.

As for the test piece 9 in which the wire diameter of the second conductive body is made as thin as approximately 0.05 mm, the resistance value of the embedded electrode is increased to approximately 10Ω, and the current-carrying capacity is decreased to approximately 0.25 A. On the other hand, as for the test piece 10 in which the wire diameter of the second conductive body is made too thick as approximately 0.35 mm, spaces between each of the mesh wires become narrow. Accordingly, it becomes difficult to fill the mesh with ceramic powder when the press forming is performed, and airgaps are generated. As a result, the shear strength is lowered to approximately 90 MPa.

As for the test piece 11 in which the mesh coarseness of the second conductive body is made as coarse as #24, processing becomes limited so that it is difficult to perform fine processing, for example. On the other hand, as for the test piece 12 in which the mesh coarseness of the second conductive body is made too fine as #100, spaces between each of the mesh wires become narrow. Accordingly, it becomes difficult to fill the mesh with ceramic powder when performing the press forming, and airgaps are generated. As a result, the shear strength is lowered to approximately 100 MPa.

### (Evaluation Result 2)

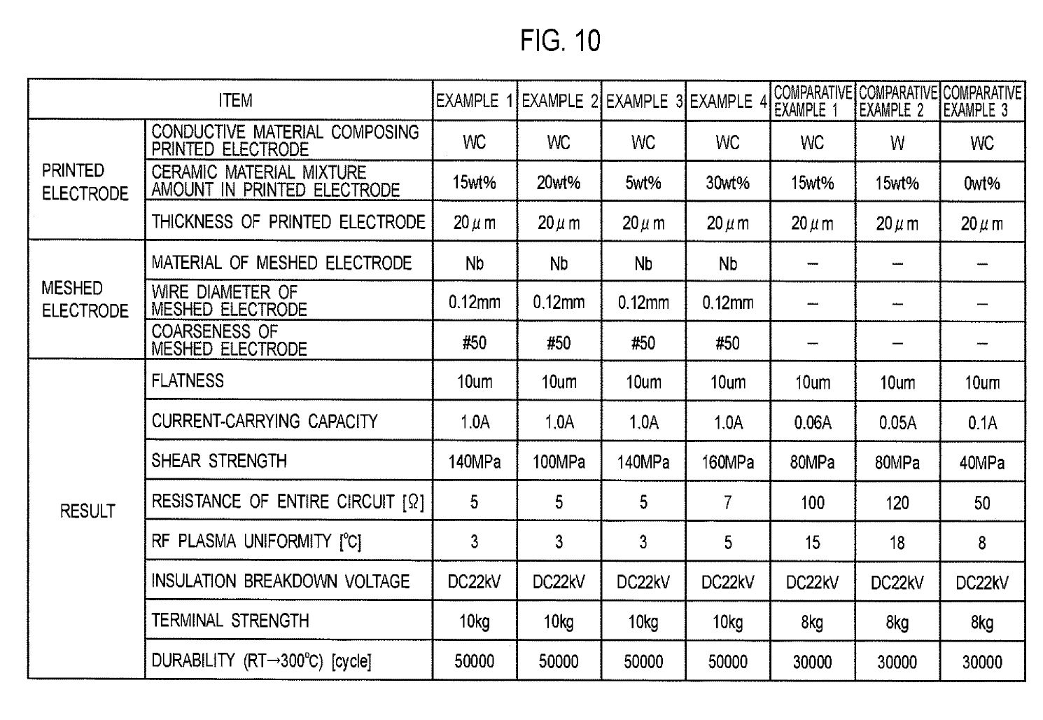

A table in FIG. 10 shows results of evaluation of various properties by taking, as example 1, a substrate support in which yttria (Y₂O₃) is used instead of alumina (Al₂O₃) as the ceramic base, Other manufacturing conditions and the like are the same as those described in the manufacturing method according to the embodiment of the present invention.

Specifically, the manufacturing method of the substrate support is the same as the aforementioned (a) to (e). The difference is that a Y₂O₃ powder (particle size of 1.2 μm) having 99.5% purity is used as the ceramic precursor powder, the same Y₂O₃ powder is used instead of the alumina powder for the conductive paste of the first conductive body, and an electrode formed of Nb metal is used as the second conductive body.

In comparative examples 1 to 3, the meshed second electrode (the second conductive body) is not provided. As shown in comparative examples 1 and 2, a larger shear strength than comparative example 3 can be obtained by mixing ceramic (yttria) to the printed electrode. However, when ceramic (yttria) is mixed to the printed electrode as in the comparative examples 1 and 2, resistance of the entire circuit is improved, the current-carrying capacity is lowered, and the uniformity of RF plasma is deteriorated.

Meanwhile, when a printed electrode (first conductive body) formed of paste and a meshed electrode (second conductive body) are provided as in the examples 1 to 4, the resistance of the entire circuit is largely lowered, the current-carrying capacity is increased, and the uniformity of RF plasma is improved.

As shown in the comparative examples 1 to 3, when the printed electrode (first conductive body) formed of paste alone is provided, the paste at the terminal portion is peeled off and the terminal strength is low.

On the other hand, as shown in the examples 1 to 4, when the printed electrode (first conductive body) formed of paste and the meshed electrode (second conductive body) are provided, the terminal strength is higher than the comparative examples 1 to 3.

Thus, the substrate support includes the printed electrode (first conductive body) formed of the electrode in which tungsten carbide (WC) and (yttria (Y₂O₃)) are mixed, the meshed electrode (second conductive body) formed of Nb, and the ceramic base formed of (yttria (Y₂O₃)). In the above-mentioned process of (b), a surface of the sintered body obtained in the first sintering is smoothed, and a dielectric film portion (sintered body 12A) is obtained by the second sintering described in the process of (d). This makes it possible to form the dielectric film having the flat surface on which the substrate is placed and having the even thickness. Thus, the electrostatic chuck including the embedded electrode to which a large current is applicable can be provided.

What is claimed is:

1. A substrate support, comprising:
a ceramic base composed of any one of aluminum nitride (AlN), alumina (Al₂O₃), yttria (Y₂O₃), silicon nitride (Si₃N₄), silicon carbide (SiC) and boron nitride (BN), and having an upper surface on which a substrate is placed;
a first conductive body having a plate-type body, composed of a sintered material of a conductive paste, and embedded in an upper side of the ceramic base;
a second conductive body having a meshed-type body, provided inside the ceramic base, and being in contact with a lower surface of the first conductive body; and
an electrode terminal penetrating a part of the ceramic base from a lower surface of the ceramic base and being connected to the second conductive body, wherein
the conductive paste forming the first conductive body includes at least a high melting point metal composed of any one of molybdenum (Mo), niobium(Nb) and tungsten(W), or a high melting point metal carbide composed of any one of Mo, Nb, and W,
the conductive paste forming the first conductive body includes 5 wt % to 30 wt % of a ceramic powder made of a same material as the ceramic base, and
a thickness of the first conductive body is 10 μm to 30 μm.

2. The substrate support according to claim 1, wherein the second conductive body is composed of a same metal as the high melting point metal included in the conductive paste

3. The substrate support according to claim 1, wherein a difference between a thermal expansion rate of the ceramic base and a thermal expansion rate of a conductive material composing the first conductive body, and a difference between a thermal expansion rate of the ceramic base and a thermal expansion rate of a conductive material composing the second conductive body is equal to or smaller than 5×10⁻⁶/K, respectively.

4. The substrate support according to claim 1, wherein an outer edge of the second conductive body is placed at an inner side of an outer circumference of the first conductive body.

5. The substrate support according to claim 1, wherein a wire diameter of the second conductive body is approximately 0.05 to 0.35 mm, and a mesh coarseness of the second conductive body is approximately #24 to #100.

6. A substrate support, comprising:
a ceramic base composed of yttria (Y₂O₃),and having an upper surface on which a substrate is placed;
a printed electrode having a plate-type body, composed of a sintered material of a conductive paste, and embedded in an upper side of the ceramic base;
a meshed electrode having a meshed-type body, provided inside the ceramic base, being in contact with a lower surface of the printed electrode, and composed of niobium(Nb); and
an electrode terminal penetrating a part of the ceramic base from a lower surface of the ceramic base and being connected to the meshed electrode, wherein
the conductive paste forming the printed electrode is composed of a mixed material of tungsten carbide (WC) and yttria (Y₂O₃),
the conductive paste forming the printed electrode includes 5 wt % to 30 wt % of a ceramic powder made of yttria (Y₂O₃), and
a thickness of the printed electrode is 10 μm to 30 μm.
